(19) United States
(12) Patent Application Publication
(10) Pub. No.: US 2009/0108957 A1
(43) Pub. Date: Apr. 30, 2009

(54) PHASE SHIFTER

(75) Inventor: Jr-Ren JENG, Taipei (TW)

Correspondence Address: Workman Nydegger;1000 Eagle Gate Tower, 60 East South Temple, Salt Lake City, UT, 84111, US

(73) Assignee: SMARTANT TELECOM CO., LTD., Jhudong Township (TW)

(21) Appl. No.: 11/925,592

(22) Filed: Oct. 26, 2007

(51) Int. Cl. H03H 7/18

(52) U.S. Cl. 333/138

(57) ABSTRACT

A phase shifter includes a metal plate, a support portion, a slot, a coupling portion, and a ground portion. The phase shifter effectively improves signal coupling efficiency, and inhibits noise generated with the change of phase shift due to signal transmission. The phase shifter is advantageous in smaller volume, easy to assemble, and low cost.

### BACKGROUND OF THE INVENTION

1. Field of Invention

The present invention relates to a phase shifter, and more particularly to a phase shifter with slot coupling.

2. Related Art

With the development of wireless communication technology, wireless communication products are becoming more and more important in daily life. Moreover, people now require the communication products to be capable of transmitting video or online browsing instead of merely transmitting voice and messages. As compared with paying little attention on the appearance in the past, people now emphasizes on the products being “light, thin, short and small”, and capable of providing various communication services. As the communication products are developing in the trend of broadband and integration of multiple functions, the antennae for receiving and transmitting signals require wider bandwidth, so as to achieve high transmission speed and provide various communication services.

Phase shifters are often used in the fields of communications, instruments, and control. Though having many applications, they still have quite a number of problems to solve. For example, as the phase shifters are formed with metal structures, the coupling efficiency is unsatisfactory, or as the signal transmission is done in a contact mode, noise will be generated with the change of phase shift. Moreover, normal phase shifters have large volumes, and metal structures, so it is quite complex to fabricate.

Therefore, it has become a problem for researchers to solve to provide a phase shifter that effectively improves the signal coupling efficiency, effectively inhibits the noise generated with the change of the phase shift due to the signal transmission, and has a smaller volume.

### SUMMARY OF THE INVENTION

Accordingly, the present invention is directed to providing a phase shifter, which effectively realizes wide broadband, small volume, easy to assemble, and low cost.

The phase shifter of the present invention includes a metal plate, having a first surface and a second surface paralleling to the first surface; a support portion, located on the first surface of the metal plate for receiving a feed-in signal from a signal feed-in end; a slot, formed on the first surface of the metal plate, for transmitting the feed-in signal received by coupling to signal output end; a coupling portion, connected to the support portion, for coupling the feed-in signal to the slot; a ground portion, located beneath the second surface of the metal plate vertically, for simplifying the architecture and reduce volume of the phase shifter.

The phase shifter disclosed in the present invention couples the feed-in signal to the slot through the coupling portion, and transmitting the signal out from the slot, thereby effectively improving the signal coupling efficiency, and inhibiting noise generated with the change of phase shift due to the signal transmission, so as to realize the effect of an energy distributor. Moreover, as the support portion is movable, the phase of the signal is changed when the support portion is moved, so as to realize the effect of a phase shifter.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is a schematic view of a first embodiment of the present invention;

FIG. 2 is a schematic view of a second embodiment of the present invention;

FIG. 3 is a schematic view of a third embodiment of the present invention;

FIG. 4 is a schematic view of a fourth embodiment of the present invention;

FIG. 5 is a schematic view of a fifth embodiment of the present invention;

FIG. 6 shows an input return loss in an input bandwidth simulated according to the third embodiment; and

FIG. 7 shows a signal loss at a signal output end obtained from simulation when the third embodiment is used as an energy distributor.

### DETAILED DESCRIPTION OF THE INVENTION

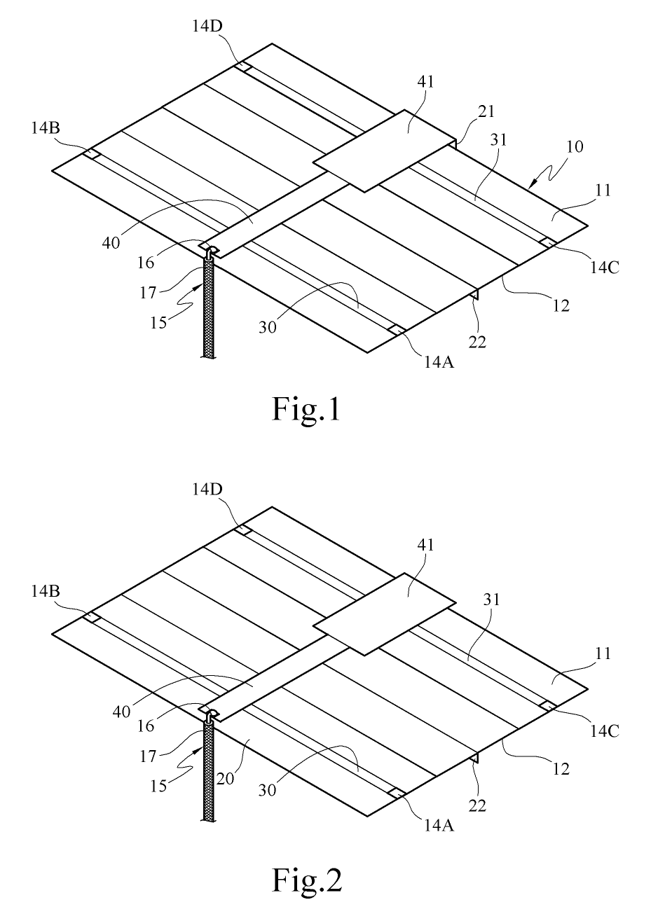

FIG. 1 is a schematic view of a first embodiment of the present invention. As shown in FIG. 1, the phase shifter includes a metal plate 10, a signal transmission line 15, a first support portion 21, a first slot 30, a second slot 31, a first coupling portion 40, and a second coupling portion 41.

The metal plate 10 has a first surface 11 and a second surface 12.

The signal transmission line 15 and the first support portion 21 are connected to two opposite edges of the first surface 11 respectively, and support the first coupling portion 40 and the second coupling portion 41 respectively. An internal signal line 16 of the signal transmission line 15 is connected to the first coupling portion 40, and an external grounding metal sheathing 17 of the signal transmission line 15 is connected to the first surface 11 of the metal plate 10, so as to receive a signal and feed the signal into the first coupling portion 40. The signal transmission line 15 and the first support portion 21 can be connected to the first surface 11 by bonding or another manner.

An end of the first coupling portion 40 is connected to the second coupling portion 41, and the other end is connected to the internal signal line 16 of the signal transmission line 15. Another end of the second coupling portion 41 is connected to the second support portion 21. The first coupling portion 40 and the second coupling portion 41 span across the first slot 30 and the second slot 31 respectively, and couple the feed-in signal to the corresponding first slot 30 and second slot 31 respectively. The first coupling portion 40 and the second coupling portion 41 are a one-piece formed metal sheet, or are different metal sheets that are bonded together.

The first slot 30 and the second slot 31 are formed on the first surface 11 of the metal plate 10, so as to transmit the feed-in signal received by coupling to signal output portions 14A, 14B, 14C, and 14D. The signal output portions 14A, 14B, 14C, and 14D are located on two ends of the first slot 30 and two ends of the second slot 31 respectively, so as to receive the feed-in signal from the first slot 30 and the second slot 31, and transmit the signal to the outside or to an external element.

The ground portion 22 is located beneath the second surface 12 of the metal plate 10, for electrically grounding the signal output portions 14.

When the feed-in signal is fed in through the signal transmission line 15, the feed-in signal is transmitted to the first coupling portion 40 and the second coupling portion 41 by the use of an impedance matching design. The areas of the first coupling portion 40 and the second coupling portion 41 may be adjusted to realize the impedance matching design, and to control the energy coupled to the signal output portions 14A, 14B, 14C, and 14D.

The first slot 30 and the second slot 31 on the first surface 11 are discontinuous surfaces relative to the first coupling portion 40 and the second coupling portion 41. Therefore, as the air serves as a dielectric, the first coupling portion 40 and the second coupling portion 41 couple the feed-in signal to corresponding positions of the first slot 30 and the second slot 31 in the first surface 11 by means of radiation transmission. Then, the first slot 30 and the second slot 31 transmit the feed-in signal received by coupling to the signal output portions 14A, 14B, 14C, and 14D, and then transmit the signal to the outside.

A ground portion 22 is located beneath the second surface 12 of the metal plate 10, and is connected to the metal plate vertically, so as to electrically ground the signal output portions 14. The ground portion 22 may be a metal sheet perpendicular to the second surface 12, a metal bolt locked on the metal plate 10, or the like. In addition, in order to prevent the coupling between the neighboring first slot 30 and second slot 31 caused by the closing space between the first slot 30 and second slot 31, the space between the first slot 30 and the second slot 31 must be increased to avoid the coupling effect between the first slot 30 and the second slot 31. However, the volume of the metal plate 10 is thus increased. At this time, as the ground portion 22 is designed isolative, the coupling between the first slot 30 and the second slot 31 may also be prevented, and the volume of the metal plate 10 will not be increased, which prevents the phase shifter from becoming larger and more costly.

As the phase shifter uses the first coupling portion 40 and the second coupling portion 41 to couple the feed-in energy signal to the corresponding first slot 30 and second slot 31, the first slot 30 and the second slot 31 will transmit the energy signal to the signal output portions 14. As the phase shifter can distribute the energy at the input end to the corresponding output ends, it can also be regarded as an energy distributor.

FIG. 2 is a schematic view of a second embodiment of the present invention. Referring to FIG. 2, the structure of the second embodiments of the present invention is different from that of the first embodiments of the present invention in terms that the second support portion 21 is removed. Thus, one end of the second coupling portion 41 is connected to the first coupling portion 40, while another end is suspended above the metal plate instead of connecting to the metal plate 10. The rest connecting methods and functions of the second embodiment are the same as those of the first embodiment, and will not be described herein again.

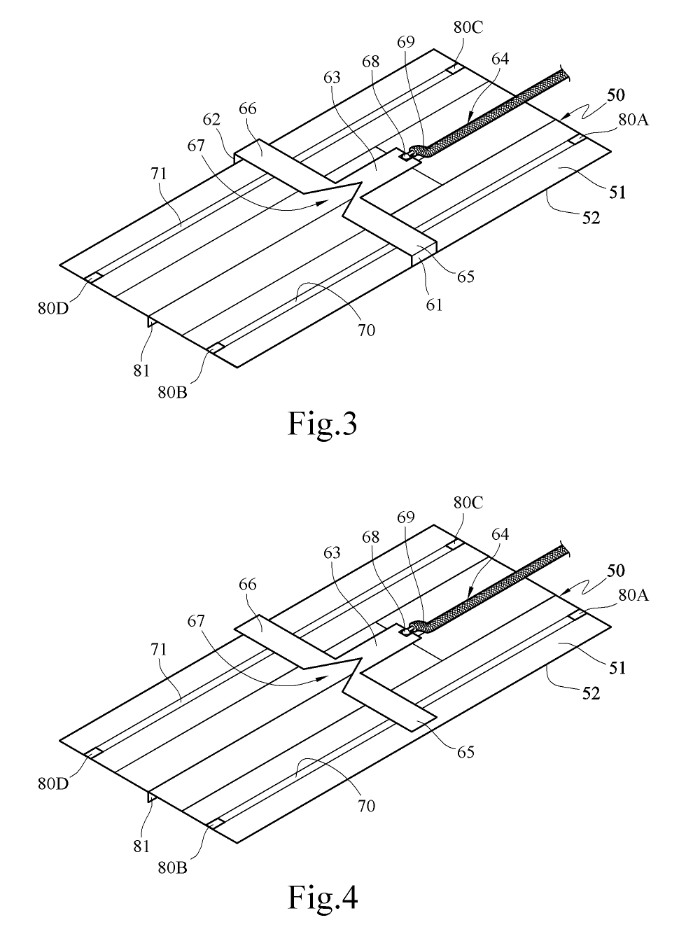

FIG. 3 is a schematic view of a third embodiment of the present invention. As shown in FIG. 3, the phase shifter includes a metal plate 50, a first support portion 61, a second support portion 62, a signal transmission portion 63, a signal transmission line 64, a first slot 70, a second slot 71, a first coupling portion 65, and a second coupling portion 66.

The metal plate 50 has a first surface 51 and a second surface 52. An internal signal line 68 of the signal transmission line 64 is connected to the signal transmission portion 63. An external grounding metal sheathing 69 of the signal transmission line 64 is connected to the first surface 51 of the metal plate 50, so as to transmit and couple the feed-in signal to the signal transmission portion 63. One end of the first support portion 61 and one end of the second support portion 62 are connected to the first coupling portion 65 and the second coupling portion 66, and another end of the first support portion 61 and another end of the second support portion 62 are located on two opposite edges of the metal plate 50 respectively.

The first coupling portion 65 spans across the first slot 70. One end of the first coupling portion 65 is connected to the first support portion 61, and another end is connected to the signal transmission portion 63, so as to couple the feed-in signal from the signal transmission portion 63 to the corresponding first slot 70. The second coupling portion 66 spans across the second slot 71. One end of the second coupling portion 66 is connected to the second support portion 62, and another end is connected to the signal transmission portion 63, so as to couple the feed-in signal from the signal transmission portion 63 to the corresponding second slot 71. The signal transmission portion 63, the first coupling portion 65, and the second coupling portion 66 are interconnected as a whole. In another embodiment, a V-shaped notch 67 is formed at the junction of the first coupling portion 65 and the second coupling portion 66.

The first slot 70 and the second slot 71 are formed in the first surface 51 of the metal plate 50, so as to transmit the feed-in signal received by coupling to the signal output portion 80.

Signal output ends 80A, 80B, 80C, and 80D are located on two ends of the first slot 70 and two ends of the second slot 71 respectively, so as to transmit the feed-in signals received from the first slot 70 and the second slot 71 to the outside.

A ground portion 81 is located beneath the second surface 52 of the metal plate 50, so as to electrically ground the signal output portion 80.

When the feed-in signal is fed in from the internal signal line 68 of the signal transmission line 64, the feed-in signal is transmitted through the signal transmission portion 63 to the first coupling portion 65 and the second coupling portion 66 that are connected to the signal transmission portion 63. At this time, the first slot 70 and the second slot 71 in the first surface 51 are discontinuous surfaces relative to the first coupling portion 65 and the second coupling portion 66. Therefore, as the air serves as the dielectric, the first coupling portion 65 and the second coupling portion 66 couple the feed-in signal to corresponding positions of the first slot 70 and the second slot 71 in the first surface 51 by means of radiation transmission. Then, the first slot 70 and the second slot 71 transmit the feed-in signal received by coupling to the signal output portions 80A, 80B, 80C, and 80D, and then transmit the signal to the outside.

The signal transmission line 64, the first support portion 61, and the second support portion 62 may be connected to the first surface 51 by bonding or in another manner.

FIG. 4 is a schematic view of a fourth embodiment of the present invention. The structure of the fourth embodiment of the present invention is different from that of the third embodiments of the present invention in terms that the first support portion 61 and the second support portion 62 are removed. Thus, one end of the first coupling portion 65 and one end of the second coupling portion 66 are connected to the signal transmission portion 63, while another end of the first coupling portion 65 and another end of the second coupling portion 66 are suspended above the metal plate without connecting to the metal plate 50. The rest connecting methods and functions of the fourth embodiment are the same as those of the third embodiment, and will not be described herein again.

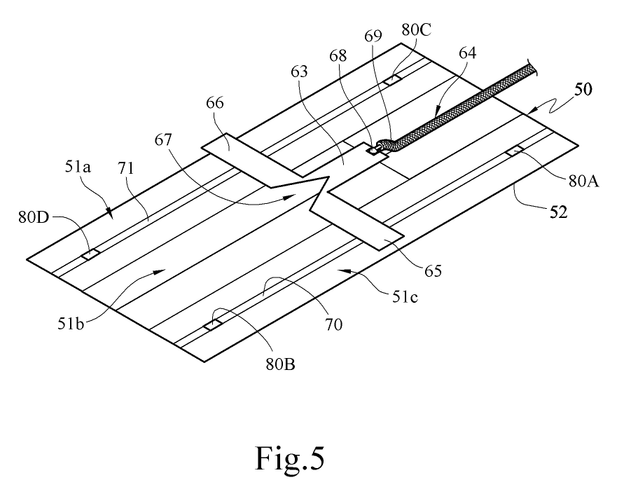

FIG. 5 is a schematic view of a fifth embodiment of the present invention. The difference between the structures of the fifth and third embodiments of the present invention is described as follows. The ground portion 81 is removed, and the positions of the signal output portions 80A, 80B, 80C, and 80D on two ends of the first slot 70 and two ends of the second slot 71 are moved inward to positions one-fourth wavelength away from edges of the slots.

When a signal is transmitted for a distance of one-fourth of its wavelength, an open loop will be formed. At this time, the first surface 51 may be regarded as three regions, namely, a region 51a between the first slot 70 and an edge of the first surface 51, a region 51b between the first slot 70 and the second slot 71, and a region 51c between the second slot 71 and the other edge of the first surface 51. The region 51b between the first slot 70 and the second slot 71 may be regarded as grounded, and the region 51a between the first slot 70 and the edge of the first surface 51 and the region 51c between the second slot 71 and the edge of the first surface 51 may be regarded at the same level. At this time, as long as the signal transmission line spans across the first slot and transversely reaches the positions of the signal output ends 14 on the first slot 70 and the second slot 71, the internal signal line of the signal transmission line is connected to the region 51a and the region 51c that are regarded at the same level. The external grounding metal sheathing of the signal transmission line is connected to the region 51b that is regarded as grounded. In this manner, the phase shifter is simplified and becomes smaller, and the ground portion 81 is omitted.

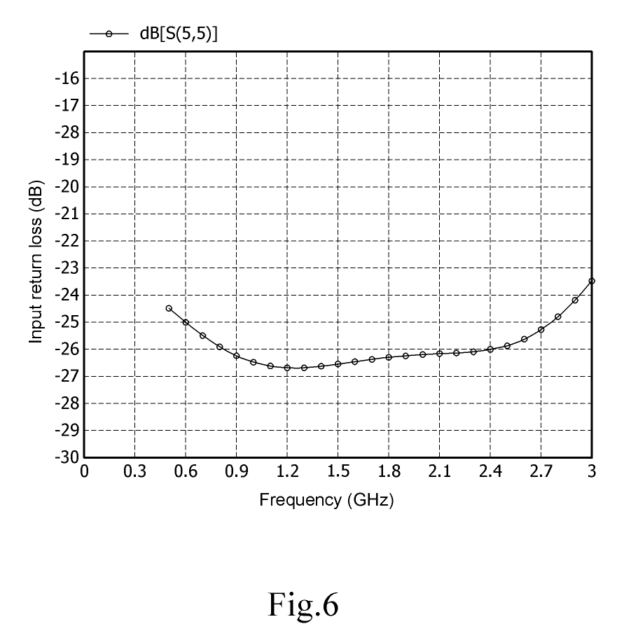

FIG. 6 shows an input return loss of −20 dB in an input bandwidth simulated according to the third embodiment, which is smaller than the loss of −10 to −15 dB of normal phase shifters.

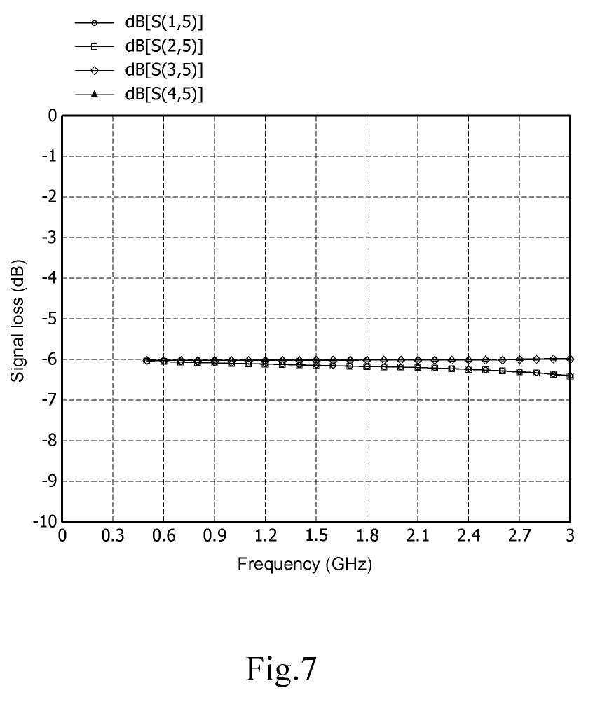

FIG. 7 shows a signal loss at a signal output end obtained from simulation when the third embodiment is used as an energy distributor, which is in conformity with the theoretical signal loss of −6 dB at the signal output end.

In the embodiments of the phase shifter of the present invention, though the long metal plate 10 and the linear slot 30 are set as an example, it should be understood that they can also be fabricated to other shapes such as round, which are not limited herein.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A phase shifter, comprising:
a metal plate, having a first surface and a second surface;
a slot, formed in the first surface of the metal plate;
a coupling portion, located on the slot, for coupling a feed-in signal to the slot; and
a signal transmission line, connecting the coupling portion and the first surface, for supporting the coupling portion on the metal plate, and feeding a signal current to the coupling portion.

2. The phase shifter as claimed in claim 1, wherein the phase shifter comprises a support portion connected to an edge of the first surface.

3. The phase shifter as claimed in claim 1, wherein the phase shifter comprises a signal transmission portion connecting the signal transmission line and the coupling portion.

4. The phase shifter as claimed in claim 1, wherein the slot comprises a first slot and a second slot.

5. The phase shifter as claimed in claim 1, wherein the coupling portion comprises a first coupling portion and a second coupling portion.

6. The phase shifter as claimed in claim 5, wherein an area of the second coupling portion is greater than an area of the first coupling portion.

7. The phase shifter as claimed in claim 2, wherein the support portion comprises a first support portion for supporting the second coupling portion on the metal plate.

8. The phase shifter as claimed in claim 2, wherein the support portion comprises a first support portion and a second support portion for supporting the first coupling portion and the second coupling portion on the first surface of the metal plate respectively.

9. The phase shifter as claimed in claim 1, wherein the phase shifter further comprises a ground portion located beneath the second surface of the metal plate vertically.

10. The phase shifter as claimed in claim 9, wherein the ground portion is one selected from a metal sheet and metal bolt groups.

11. The phase shifter as claimed in claim 1, wherein signal output portions are disposed on the slot at positions one-fourth wavelength away from an edge of the slot.
